(19) United States
(12) Patent Application Publication
(10) Pub. No.: US 2018/0145066 A1
(43) Pub. Date: May 24, 2018

(54) ESD PROTECTION CIRCUIT

(71) Applicant: SAMSUNG ELECTRO-MECHANICS CO., LTD., Suwon-si (KR)

(72) Inventor: Jae Hyun LEE, Suwon-si (KR)

(73) Assignee: SAMSUNG ELECTRO-MECHANICS CO., LTD., Suwon-si (KR)

(21) Appl. No.: 15/704,459

(22) Filed: Sep. 14, 2017

(30) Foreign Application Priority Data
Nov. 24, 2016 (KR) 10-2016-0157396

(51) Int. Cl. H01L 27/02; H01L 23/528

(52) U.S. Cl. CPC H01L 27/0262; H01L 23/5286

(57) ABSTRACT

An electrostatic discharge (ESD) protection circuit includes a silicon controlled rectifier (SCR) configured to discharge an ESD current applied to a power terminal to a ground terminal; and a p-channel metal oxide silicon (PMOS) configured to have a triggering voltage lower than that of the SCR, and to provide an ESD current path between the power terminal and the ground terminal.

### CROSS-REFERENCE TO RELATED APPLICATION(S)

This application claims the benefit under 35 USC 119(a) of Korean Patent Application No. 10-201 6-01 57396 filed on Nov. 24, 2016 in the Korean Intellectual Property Office, the entire disclosure of which is incorporated herein by reference for all purposes.

### BACKGROUND

### 1. Field

The following description relates to an electrostatic discharge (ESD) protection circuit.

### 2. Description of Related Art

An electrostatic discharge (ESD) is a phenomenon in which a high voltage electrostatic charge is instantaneously discharged, causing breakdown of semiconductor elements and metal wirings within an integrated circuit and malfunctioning of integrated circuits. In order to protect various integrated circuits, using a high voltage as a power source, from ESD, ESD in such integrated circuits should be triggered at a voltage lower than a voltage at which the integrated circuits are damaged, and a latch up effect in which thermal breakdown is caused by an excessive amount of current flowing through an ESD protection circuit should be prevented.

An element for configuring such an ESD protection circuit is a silicon controlled rectifier (SCR). In a case in which a high voltage is applied to a high voltage SCR, because the high voltage SCR has characteristics in which it is switched from a high impedance state to a low impedance state, the high voltage SCR may have high ESD resistance. However, since the high voltage SCR has a holding voltage lower than a high triggering voltage, there is a limitation in applying the high voltage SCR as a power clamp between a power source terminal and a ground terminal.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Examples provide an ESD protection circuit having a high holding voltage and improved current resistance.

In one general aspect, an electrostatic discharge (ESD) protection circuit includes a silicon controlled rectifier (SCR) configured to discharge an ESD current from a power terminal to a ground terminal; and a p-channel metal oxide silicon (PMOS) configured: to have a triggering voltage lower than that of the SCR, and to provide an ESD current path between the power terminal and the ground terminal.

The PMOS may perform a first triggering operation and the SCR may perform a second triggering operation in response to an electrostatic discharge being applied to the power terminal.

The SCR may further include an NPN-bipolar junction transistor (NPN-BJT) which may be configured to be turned-on by an avalanche breakdown between a deep n-well and a p-well in contact with the deep n-well, and a PNP-bipolar junction transistor (PNP-BJT) configured to be turned-on by the turning-on of the NPN-BJT.

A gate, a source, and a bulk terminal of the PMOS may be connected to the power terminal, and a drain of the PMOS may be connected to the ground terminal.

The PNP-BJT may be formed by a first p-type terminal formed in a deep n-well, the deep n-well, and a p-well in contact with the deep n-well, and the NPN-BJT may be formed by the deep n-well, the p-well, and an n-type terminal formed in the p-well.

A source of the PMOS may be a first p-type terminal formed in the deep n-well, a drain of the PMOS may be a second p-type terminal formed in the deep n-well, and a gate of the PMOS may be disposed between the first p-type terminal and the second p-type terminal.

According to another general aspect, an electrostatic discharge (ESD) protection circuit connected to a power terminal and a ground terminal of an integrated circuit formed on a semiconductor substrate, the ESD protection circuit includes a p-channel metal oxide silicon (PMOS) formed in a deep n-well on the semiconductor substrate, and having a source, a gate, and a bulk terminal connected to the power terminal, and a drain connected to the ground terminal; a PNP-bipolar junction transistor (PNP-BJT) sharing the deep n-well; and an NPN-bipolar junction transistor (NPN-BJT) formed in a p-well in contact with the deep n-well and having an emitter connected to the ground terminal.

The PNP-BJT and the NPN-BJT may form a silicon controlled rectifier (SCR).

In response to an electrostatic discharge being applied to the power terminal, the ESD protection circuit may perform a first triggering operation by the PMOS and then perform a second triggering operation by the SCR.

The NPN-BJT may be turned-on by an avalanche breakdown between the deep n-well and the p-well, and the PNP-BJT may be turned-on by the turning-on of the NPN-BJT.

The source may be a first p-type terminal formed in the deep n-well, the drain may be a second p-type terminal formed in the deep n-well, and the gate may be disposed between the first p-type terminal and the second p-type terminal which are formed in the deep n-well, the PNP-BJT may be formed by the first p-type terminal, the deep n-well, and the p-well, and the NPN-BJT may be formed by the deep n-well, the p-well, and an n-type terminal formed in the p-well.

According to another general aspect, an electrostatic discharge (ESD) protection circuit includes an integrated circuit (IC) core electrically intercoupled between a power terminal and a ground terminal; a semiconductor controlled rectifier (SCR) configured to discharge an ESD current from the power terminal to the ground terminal bypassing the IC core; a metal oxide semiconductor field effect transistor (MOSFET) configured: to have a triggering voltage lower than that of the SCR, and to provide an ESD current path between the power terminal and the ground terminal, bypassing the IC core.

The MOSFET and the SCR may be electrically coupled in parallel relation between the power terminal and the ground terminal.

The MOSFET may be a p-channel metal oxide semiconductor (PMOS); and, the SCR may include a PNP-bipolar junction transistor (PNP-BJT); and an NPN-bipolar junction transistor (NPN-BJT) configured to discharge an ESD current from the power terminal to the ground terminal, bypassing the IC core.

Other features and aspects will be apparent from the following detailed description, the drawings, and the claims.

### BRIEF DESCRIPTION OF DRAWINGS

FIG. 1 is a cross-sectional view illustrating an example of a configuration of an electrostatic discharge (ESD) protection circuit.

FIG. 2 is a cross-sectional view illustrating an example of a structure of a PMOS, such as the one in FIG. 1.

FIG. 3 is a cross-sectional view illustrating a structure of an SCR, such as the one in FIG. 1.

FIG. 4 is an equivalent circuit diagram of an example of an ESD protection circuit.

FIG. 5A is a graph illustrating a current and a voltage according to a transmission-line pulse (TLP) measurement for an example of the ESD protection circuit.

FIG. 5B is a graph illustrating a leakage current according to the transmission-line pulse (TLP) measurement for an example of the ESD protection circuit.

FIG. 6 is a diagram illustrating an example in which the ESD protection circuit is disposed on a semiconductor substrate.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Hereinafter, embodiments will be described in detail with reference to the accompanying drawings.

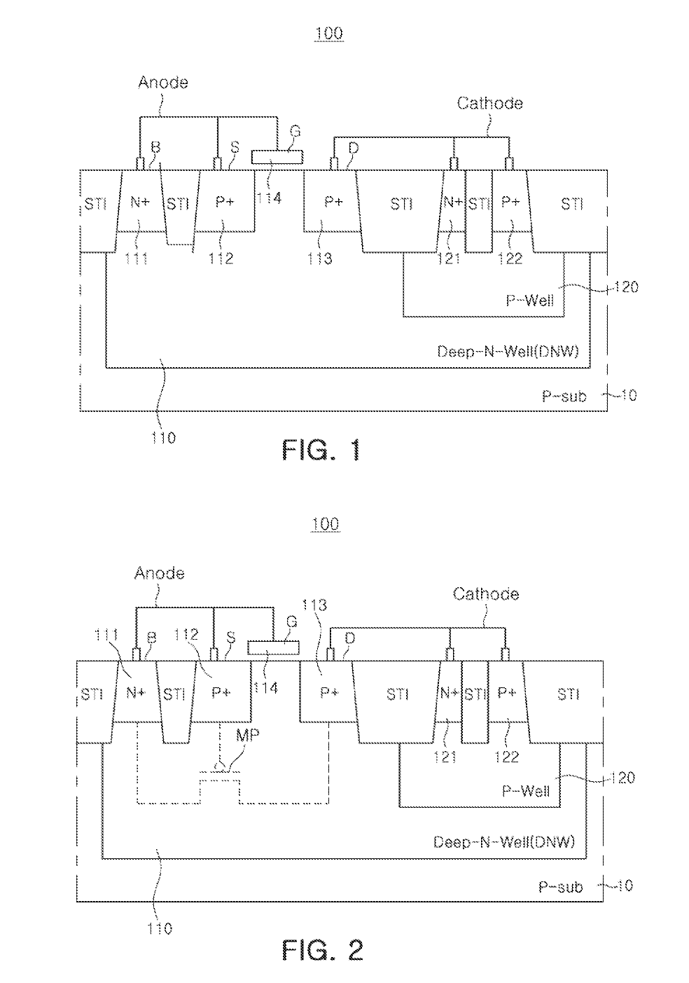

FIG. 1 is a cross-sectional view illustrating an example of a configuration of an electrostatic discharge (ESD) protection circuit.

Referring to FIG. 1, an embodiment of the ESD protection circuit 100 includes a semiconductor controlled rectifier (e.g. Germanium) or silicon controlled rectifier (SCR) and a p-channel metal oxide silicon (PMOS) or a p-channel metal oxide semiconductor (PMOS) or n-channel metal oxide semiconductor (NMOS). Other suitable metal oxide semiconductor devices such as a metal oxide semiconductor field effect transistor (MOSFET), or other suitable transistor may be employed. In addition, the SCR includes, for example, an NPN-bipolar junction transistor (NPN-BJT) and a PNP-BJT. To this end, the ESD protection circuit 100 includes a deep n-well 110 and a p-well 120 which are formed in a semiconductor substrate (P-sub) 10. As illustrated in FIG. 1, the p-well 120 is formed within the deep n-well 110.

An n-type terminal 111, a first p-type terminal 112, and a second p-type terminal 113 are formed over the deep n-well 110. Here, the n-type terminal 111 formed over the deep n-well 110 is, according to one or more embodiments, a bulk terminal B of the PMOS, the first p-type terminal 112 is a source S of the PMOS, and the second p-type terminal 113 is a drain D of the PMOS. In addition, a gate member 114 forming a gate G of the PMOS is disposed between the first p-type terminal 112 and the second p-type terminal 113. The source S and the gate G are connected to an anode together with the bulk terminal B, and the drain D is connected to a cathode.

In addition, an n-type terminal 121 and a p-type terminal 122 are formed over the p-well 120, and are connected to the cathode.

Meanwhile, the n-type terminals and the p-type terminals formed over the deep n-well 110 and the p-well 120 are n+ regions doped with an n-type impurity and p+ regions doped with a p-type impurity. In addition, a shallow trench isolation (STI) that isolates the n-type terminals and the p-type terminals is, according to embodiment, an STI formed by forming a shallow trench and then filling the shallow trench with an insulating material.

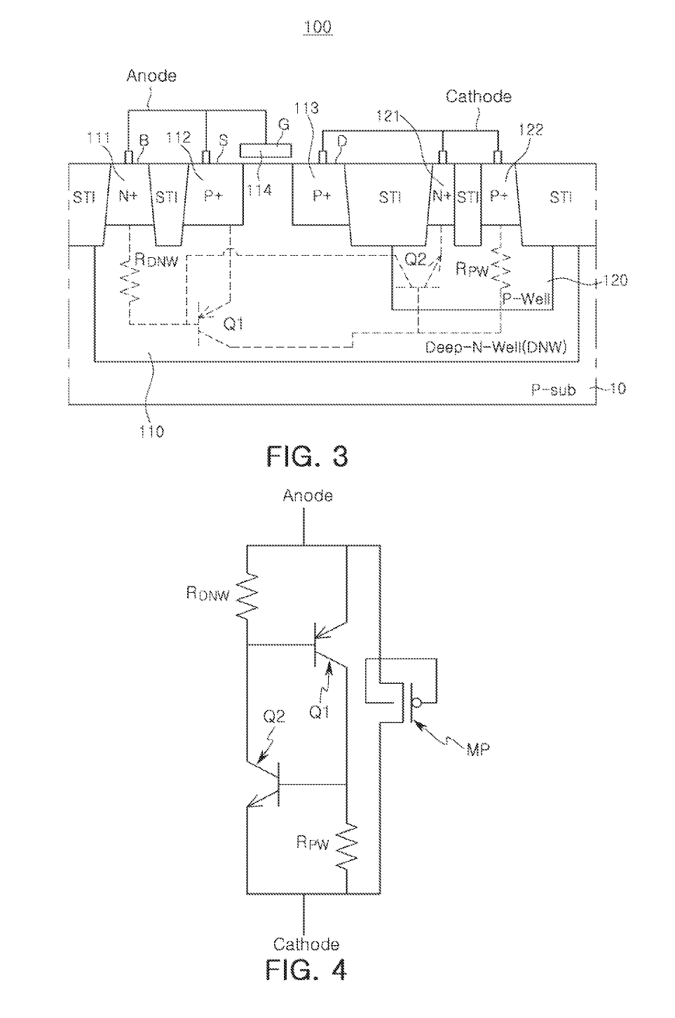

Hereinafter, a structure and an operation of the SCR and the PMOS in addition to a configuration of the ESD protection circuit are described with reference to FIGS. 2 and 3.

FIG. 2 is a cross-sectional view illustrating an example of a structure of a PMOS, such as from FIG. 1.

Referring to FIG. 2, the PMOS (MP) is formed, according to an embodiment, by the deep-n-well 110, the n-type terminal 111, the first p-type terminal 112, and the second p-type terminal 113 which are formed in the deep-n-well 110, and the gate member 114. As described above with reference to FIG. 1, a source S of the PMOS MP is the first p-type terminal 112 formed in the deep-n-well 110, a drain D of the PMOS MP is the second p-type terminal 113 formed in the deep-n-well 110, and a gate of the PMOS MP is the gate member 114 disposed between the first p-type terminal 112 and the second p-type terminal 113.

Hereinafter, an operation of the PMOS MP in a case in which an electrostatic discharge is applied to an anode is described. In a case in which the electrostatic discharge is applied to the anode, a gate—source voltage Vgs may be zero (0), and the PMOS MP is in a turned-off state. Thereafter, a voltage at the anode may be sharply increased, and the deep-n-well 110 and the second p-type terminal 113 may be in a reverse bias state. In a case in which the voltage of the anode arrives at an avalanche breakdown voltage of the PMOS MP, a negative resistance state may occur due to a snapback effect. The anode voltage may be referred to as a triggering voltage of the PMOS MP. That is, in a case in which an avalanche breakdown occurs and a voltage drop occurs due to a current provided from the bulk terminal B, a parasitic PNP transistor of the PMOS MP is turned-on, and a current path having low resistance in which an electrostatic discharge current flows from the source S to the drain Dis provided. The above-mentioned triggering operation of the PMOS MP will be referred to as a first triggering operation of the electrostatic discharge protection circuit 100.

FIG. 3 is a cross-sectional view illustrating a structure of an SCR, such as the one in FIG. 1.

Referring to FIG. 3, the electrostatic discharge protection circuit 100 includes the SCR including a PNP-BJT Q1 and an NPN-BJT Q2. The PNP-BJT Q1 is formed by the first p-type terminal 112 formed in the deep-n-well 110, the deep-n-well 110, and the p-well 120 in contact with the deep-n-well 110. In addition, the NPN-BJT Q2 is formed by the deep-n-well 110, the p-well 120, and the n-type terminal 121 formed in the p-well 120. That is, the PNP-BJT Q1 and the NPN-BJT Q2 configure the SCR of a PNPN structure.

Hereinafter, an operation of the SCR of a case in which the electrostatic discharge is applied to the anode is described. After the first triggering operation by the PMOS MP, as the electrostatic discharge voltage applied to the anode is increased, the avalanche breakdown may occur between the deep-n-well 110 and the p-well 120 in the reverse bias state. If a potential of the p-well 120 becomes sufficiently high by a hole current generated in this case (V_{BE}>0V), the NPN-BJT Q2 is turned-on. A current of the turned-on NPN-BJT Q2 causes a voltage drop across R_{DNW} (V_{BE}<0), and the PNP-BJT Q1 is turned-on. As such, a voltage at which the PNP-BJT Q1 and NPN-BJT Q2 are turned-on may be referred to as a triggering voltage of the SCR. Thereafter, the turned-on PNP-BJT Q1 causes a voltage drop across R_{PW}, and the NPN-BJT Q2 maintains the turned-on state by the current of the PNP-BJT Q1. That is, because there is no need to supply a bias, the voltage of the anode may be decreased up to the holding voltage. The above-mentioned triggering operation of the SCR will be referred to as a second triggering operation of the electrostatic discharge protection circuit 100.

FIG. 4 is an equivalent circuit diagram of an example of an ESD protection circuit.

Referring to FIG. 4, the ESD protection circuit includes, according to an embodiment, the SCR including the PNP-BJT Q1 and NPN-BJT Q2, and the PMOS MP. In order to discharge the electrostatic discharge (ESD), the SCR and the PMOS MP provide an electrostatic discharge current path. Because the triggering voltage of the PMOS MP is lower than the triggering voltage of the SCR, the triggering operation of the PMOS MP is performed before the triggering operation of the SCR in a case in which the electrostatic discharge is applied to the anode. That is, the ESD protection circuit adopting the PMOS MP is operable at a lower triggering voltage. In addition, a latch up risk caused by the snapback is removed from the ESD protection circuit.

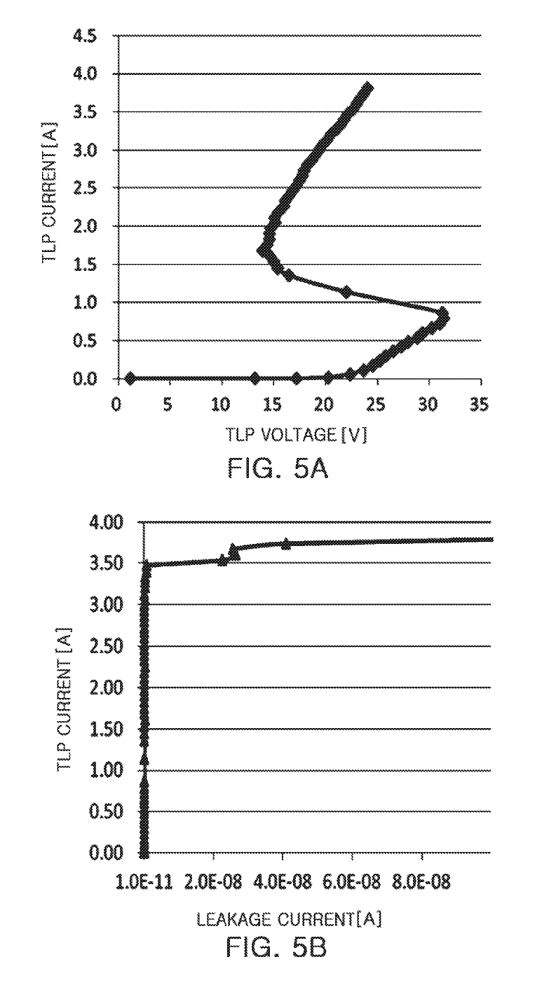

FIGS. 5A and 5B are graphs illustrating characteristics of a current and a voltage and characteristics of a leakage current according to a transmission-line pulse (TLP) measurement for an example of the ESD protection circuit. The TLP measurement, a test method that supplies a continuous current pulse between 5 ns to 100 ns to a device under test (DUT) while gradually increasing the current pulse, and measures a current and a voltage of the DUT, may be utilized as a measure of measuring performance of the ESD protection circuit.

Referring to FIGS. 5A and 5B, the ESD protection circuit, for example, starts the first triggering operation by the PMOS at about 18V, a relatively lower voltage than a triggering voltage of the SCR according to related art. In addition, after the triggering operation of the PMOS, the ESD protection circuit starts the second triggering operation by the SCR at about 30V.

It is seen in FIG. 5A that the ESD protection circuit has a holding current of, for example, about 1.5A and a holding voltage of about 15V. As such, the relatively high holding current and holding voltage beneficially act to prevent a latch up in which a thermal breakdown is caused by an excessively high current flowing through the ESD protection circuit.

In addition, it is seen in FIG. 5B that a TLP current is about 3.5A. This value sufficiently satisfies a peak current standard value of about 1.33A when an equivalent circuit of 1.5 kΩ is assumed in a human body mode HBM, an ESD model. Therefore, a size of the ESD protection circuit may be, according to an embodiment, further reduced.

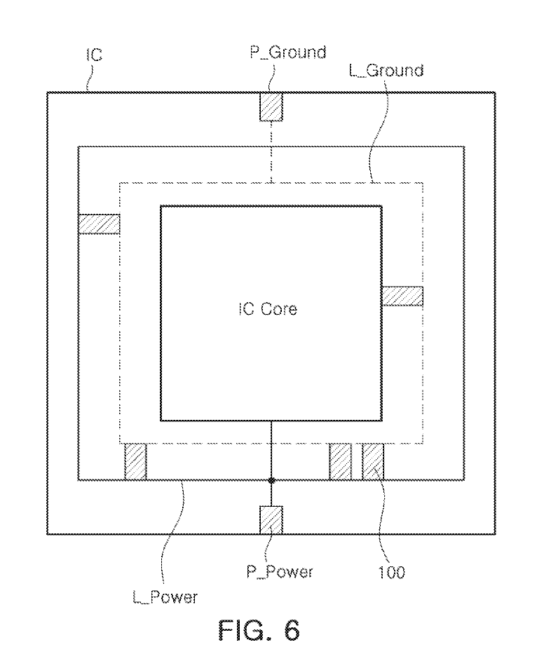

FIG. 6 is a diagram illustrating an example in which the ESD protection circuit is disposed on a semiconductor substrate.

Referring to FIG. 6, an integrated circuit (IC) on the semiconductor substrate includes, for example, a power wire L_Power, a ground wire L_Ground, and an integrated circuit (IC) core. The power wire L_Power is applied with power from the outside (such as an external power supply) through a power pin P_Power, and the ground wire L_Ground is grounded through a ground pin P_Ground. The power clamp is disposed, for example, between the power wire L_Power and the ground wire L_Ground. Through such a layout, the power clamp is operable to prevent a breakdown of the integrated circuit (IC) including the IC core. Because the ESD protection circuit 100 has the high holding voltage and an improved current resistance to the high voltage, it may be utilized as the power clamp that implements high reliability.

As set forth above, because the ESD protection circuit has the high holding voltage and the improved current resistance, it may be used as the high voltage power clamp that implements high reliability.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

Due to manufacturing techniques and/or tolerances, variations of the shapes shown in the drawings may occur. Thus, the examples described herein are not limited to the specific shapes shown in the drawings, but include changes in shape that occur during manufacturing.

Expressions such as “first conductivity type” and “second conductivity type” as used herein may refer to opposite conductivity types such as N and P conductivity types, and examples described herein using such expressions encompass complementary examples as well. For example, an example in which a first conductivity type is N and a second conductivity type is P encompasses an example in which the first conductivity type is P and the second conductivity type is N.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electrostatic discharge (ESD) protection circuit comprising:
a silicon controlled rectifier (SCR) configured to discharge an ESD current from a power terminal to a ground terminal; and
a p-channel metal oxide silicon (PMOS) configured:
to have a triggering voltage lower than that of the SCR, and
to provide an ESD current path between the power terminal and the ground terminal.

2. The ESD protection circuit of claim 1, wherein the PMOS is configured to perform a first triggering operation, and the SCR is configured to perform a second triggering operation in response to ESD being applied to the power terminal.

3. The ESD protection circuit of claim 1, wherein the SCR further comprises an NPN-bipolar junction transistor (NPN-BJT), NPN-BJT is configured to be turned-on by an avalanche breakdown between a deep n-well and a p-well in contact with the deep n-well; and
a PNP-bipolar junction transistor (PNP-BJT), the PNP-BJT is configured to be turned-on by the turning-on of the NPN-BJT.

4. The ESD protection circuit of claim 3, wherein a gate, a source, and a bulk terminal of the PMOS are connected to the power terminal, and
a drain of the PMOS is connected to the ground terminal.

5. The ESD protection circuit of claim 1, wherein the PNP-BJT is formed by a first p-type terminal formed in a deep n-well, the deep n-well, and a p-well in contact with the deep n-well, and
the NPN-BJT is formed by the deep n-well, the p-well, and an n-type terminal formed in the p-well.

6. The ESD protection circuit of claim 3, wherein a source of the PMOS is a first p-type terminal formed in the deep n-well,
a drain of the PMOS is a second p-type terminal formed in the deep n-well, and
a gate of the PMOS is disposed between the first p-type terminal and the second p-type terminal.

7. An electrostatic discharge (ESD) protection circuit connected to a power terminal and a ground terminal of an integrated circuit formed on a semiconductor substrate, the ESD protection circuit comprising:
a p-channel metal oxide silicon (PMOS) formed in a deep n-well on the semiconductor substrate, and comprising a source, a gate, and a bulk terminal connected to the power terminal, and a drain connected to the ground terminal;
a PNP-bipolar junction transistor (PNP-BJT) sharing the deep n-well; and
an NPN-bipolar junction transistor (NPN-BJT) formed in a p-well in contact with the deep n-well and having an emitter connected to the ground terminal.

8. The ESD protection circuit of claim 7, wherein the PNP-BJT and the NPN-BJT form a silicon controlled rectifier (SCR).

9. The ESD protection circuit of claim 8, wherein in response to an electrostatic discharge being applied to the power terminal, the ESD protection circuit performs a first triggering operation by the PMOS and then performs a second triggering operation by the SCR.

10. The ESD protection circuit of claim 7, wherein the NPN-BJT is turned-on by an avalanche breakdown between the deep n-well and the p-well, and the PNP-BJT is turned-on by the turning-on of the NPN-BJT.

11. The ESD protection circuit of claim 7, wherein the source is a first p-type terminal formed in the deep n-well, the drain is a second p-type terminal formed in the deep n-well, and the gate is disposed between the first p-type terminal and the second p-type terminal, which are formed in the deep n-well,
the PNP-BJT is formed by the first p-type terminal, the deep n-well, and the p-well, and
the NPN-BJT is formed by the deep n-well, the p-well, and an n-type terminal formed in the p-well.

12. An electrostatic discharge (ESD) protection circuit comprising:
an integrated circuit (IC) core electrically intercoupled between a power terminal and a ground terminal;
a semiconductor controlled rectifier (SCR) configured to discharge an ESD current from the power terminal to the ground terminal bypassing the IC core;
a metal oxide semiconductor field effect transistor (MOSFET) configured:
to have a triggering voltage lower than that of the SCR, and
to provide an ESD current path between the power terminal and the ground terminal, bypassing the IC core.

13. The ESD protection circuit of claim 13, wherein the MOSFET and the SCR are coupled in parallel relation between the power terminal and the ground terminal.

14. The ESD protection circuit of claim 14, wherein MOSFET is a p-channel metal oxide semiconductor; and,
the SCR comprises
a PNP-bipolar junction transistor (PNP-BJT), and
an NPN-bipolar junction transistor (NPN-BJT) configured to discharge an ESD current from the power terminal to the ground terminal, bypassing the IC core.
